(19) United States
(12) Patent Application Publication
(10) Pub. No.: US 2008/0079105 A1
(43) Pub. Date: Apr. 3, 2008

(54) Sensor-type package and fabrication method thereof

(75) Inventors: Tse-Wen Chang, Taichung Hsien (CN); Chang-Yueh Chan, Taichung Hsien (CN); Chien-Ping Huang, Taichung Hsien (CN); Chih-Ming Huang, Hsinchu Hsien (CN); Cheng-Hsu Hsiao, Taichung Hsien (CN)

Correspondence Address: EDWARDS ANGELL PALMER & DODGE LLP, P.O. BOX 55874, BOSTON, MA, 02205, US

(73) Assignee: Siliconware Precision Industries Co., Ltd., Taichung (CN)

(21) Appl. No.: 11/904,648

(22) Filed: Sep. 27, 2007

(30) Foreign Application Priority Data
Sep. 28, 2006 (TW) 095135932

(51) Int. Cl. H01L 31/0203; H01L 21/02

(52) U.S. Cl. 257/434; 438/116; 257/E21.536; 257/E31.117

(57) ABSTRACT

A sensor-type package and a fabrication method thereof are provided. A sensor-type chip is mounted on a substrate and is electrically connected to the substrate via bonding wires. A light-pervious body is attached to the sensor-type chip, and has one surface covered with a covering layer and another surface formed with an adhesive layer. An encapsulant encapsulates the light-pervious body. As an adhesive force between the covering layer and the encapsulant is greater than that between the covering layer and the light-pervious body, the covering layer and a portion of the encapsulant located on the covering layer can be concurrently removed, such that the light-pervious body is exposed and light can pass through the light-pervious body to be captured by the sensor-type chip. The above arrangement eliminates the need of using a dam structure as in the prior art and provides a compact sensor-type package with improved fabrication reliability.

### FIELD OF THE INVENTION

The present invention relates generally to semiconductor packages and fabrication methods thereof, and more particularly, to a sensor-type package and a method of fabricating the sensor-type package.

### BACKGROUND OF THE INVENTION

Conventionally, to fabricate an image sensor package, a sensor-type chip is mounted on a chip carrier and is electrically connected to the chip carrier via a plurality of bonding wires, and then a glass member is provided above the sensor-type chip, allowing the sensor-type chip to capture image light passing through the glass member. Such an image sensor package is generally assembled into an external device, such as a printed circuit board, for use in various electronic products such as a digital camera, digital video camera, mobile phone, finger print sensor, and the like.

Referring to FIG. 1, a sensor-type package disclosed by U.S. Pat. No. 6,060,340 is shown. A dam structure 13 is formed and is attached to a substrate 11 via an adhesive 16. The dam structure 13 is further formed with a receiving space 14 for receiving a sensor-type chip 10 mounted on the substrate 11 and bonding wires 12 for electrically connecting the sensor-type chip 10 to the substrate 11. A glass member 15 is attached to the dam structure 13, for sealing the receiving space 14 and thereby isolating the sensor-type chip 10 and the bonding wires 12 from the ambient. However, as the adhesive 16 is of high moisture absorptivity, in a high temperature environment of subsequent processes, the adhesive 16 tends to absorb moisture of the ambient and can cause a popcorn effect, thereby leading to delamination of the dam structure from the substrate and reducing the package reliability.

Referring to FIGS. 2A and 2B, another sensor-type package is shown as disclosed by U.S. Pat. Nos. 6,262,479 and 6,590,269. As shown in FIG. 2A, a molding process is performed to form a dam structure 23 on a substrate 21. During molding, a packaging mold including an upper mold 27 and a lower mold 28 is used. The upper mold 27 has an upper mold cavity 270 and a protruding portion 271 formed in the upper mold cavity 270. The substrate 21 can be disposed between the upper mold 27 and the lower mold 28, with the protruding portion 271 contacting the substrate 21 to cover predefined chip-mounting and wire-bonding areas of the substrate 21. Subsequently, a resin compound (such as an epoxy resin) is injected into the upper mold cavity 270 so as to form a dam structure 23 on the substrate 21. After the upper mold 27 and the lower mold 28 are removed, the chip-mounting and wire-bonding areas of the substrate 21 are exposed without being covered by the dam structure 23. As shown in FIG. 2B, a sensor-type chip 20 and bonding wires 22 are disposed on the exposed areas of the substrate 21. Finally, a glass member 25 is attached to the dam structure 23. Thereby, the sensor-type package is obtained.

However, the above sensor-type package causes some significant drawbacks. For example, a clamping force between the protruding portion and the substrate is not easy to control. If the protruding portion cannot stably and closely abut against the substrate, the resin compound would easily flash through a gap between the protruding portion and the substrate and thereby contaminate the chip-mounting and wire-bonding areas. On the other hand, if the protruding portion is too tightly pressed against the substrate, the substrate would be damaged. Further, the mold needs to have its protruding portion sized according to the size of the predefined areas of the substrate and is not cost effective to fabricate. In other words, if the size of the predefined areas of the substrate is changed, a new mold having an appropriate protruding portion should be prepared, thereby undesirably increasing the fabrication cost and complicating the fabrication process.

FIG. 3 shows a sensor-type package disclosed by U.S. Pat. No. 5,950,074. Referring to FIG. 3, a fluid adhesive is applied on a substrate 31 to form a dam structure 33. A glass member 35 is attached to the dam structure 33, and covers a sensor-type chip 30 and bonding wires 32 disposed on the substrate 31 in a receiving space defined by the dam structure 33.

However, a common problem exists in the above-described techniques. That is, the chip size, the space for bonding wires and the width of the dam structure all account for the package size. Particularly, the package must include a space reserved for accommodating the dam structure, thereby making it difficult to further reduce the package size.

Accordingly, Taiwan Patent No. 521440 discloses another sensor-type package as shown in FIG. 4A. In this sensor-type package, a sensor-type chip 40 having a sensor area on an active surface thereof is mounted on a substrate 41, and is electrically connected to the substrate 41 via a plurality of bonding wires 42. An adhesive 43 is applied on the bonding wires 42 around the sensor-type chip 40 to form a dam structure. The height of the adhesive 43 is larger than the thickness of the sensor-type chip 40. A light-pervious layer 45 is directly attached to the adhesive 43 by the adhesiveness of the adhesive 43.

The above dam structure formed by the adhesive applied on the bonding wires must serve both as a barrier and an adhesive member. Therefore, on one hand, the adhesive needs to have certain rigidity to form the dam structure with satisfactory structural strength, which can be achieved by adding suitable fillers to the adhesive; however, such arrangement reduces an adhesive force between the adhesive and the light-pervious layer. On the other hand, to enhance the adhesive force between the adhesive and the light-pervious layer, the amount of fillers should be decreased, which however reduces the rigidity of the dam structure, and thereby easily causes leakage of the light-pervious layer and reduces the package reliability.

Moreover, the light-pervious layer needs to be attached to the adhesive before the adhesive is completely solidified. The adhesive generally tends to be solidified and hardened before the light-pervious layer is attached thereto. Thus, the bonding wires can be easily damaged or cracked by the attaching pressure of the light-pervious layer.

Referring to FIG. 4B, a similar technique is disclosed by U.S. Pat. No. 6,995,462. A light-pervious layer 450 is attached to a sensor-type chip 400 before bonding wires 420 are formed, so as to protect the sensor-type chip 400 from being contaminated by external environmental particles. Thereafter, the bonding wires 420 are bonded to the sensor-type chip 400, and are encapsulated by a liquid adhesive 430 made of polymer. Such arrangement may solve the problem of leakage of the light-pervious layer 450 and cracking of the bonding wires 420, but still causes significant drawbacks of having low productivity and high fabrication cost because the fluid adhesive is expensive and is applied on the substrate primarily by a dispensing technique.

Therefore, the problem to be solved here is to develop a sensor-type package and a fabrication method thereof, which can overcome the above drawbacks.

### SUMMARY OF THE INVENTION

In view of the above drawbacks in the prior art, an objective of the present invention is to provide a light, thin and compact sensor-type package and a fabrication method thereof.

Another objective of the present invention is to provide a sensor-type package and a fabrication method thereof, which can prevent leakage of a light-pervious layer and delamination of a dam structure formed by a fluid adhesive.

Still another objective of the present invention is to provide a sensor-type package and a fabrication method thereof, which can prevent damage to and cracking of bonding wires when a light-pervious layer is attached to a dam structure formed by a fluid adhesive.

A further objective of the present invention is to provide a sensor-type package and a fabrication method thereof, without the need of forming a dam structure, thereby improving the fabrication reliability and reducing the fabrication cost.

A further objective of the present invention is to provide a sensor-type package and a fabrication method thereof, which can avoid the high fabrication cost and low productivity caused by using a liquid adhesive applied in a dispensing manner.

A further objective of the present invention is to provide a sensor-type package and a fabrication method thereof, which can employ a conventional molding process and thereby reduce the fabrication cost.

A further objective of the present invention is to provide a sensor-type package and a fabrication method thereof, which can employ a conventional molding process to fabricate the sensor-type package in a batch-type manner, thereby reducing the fabrication cost.

In order to attain the above and other objectives, the present invention discloses a fabrication method of a sensor-type package, comprising the steps of: attaching a sensor-type chip to a substrate, the sensor-type chip having an active surface and a non-active surface opposed to the active surface, wherein the non-active surface of the sensor-type chip is attached to the substrate, and the active surface of the sensor-type chip is electrically connected to the substrate via a plurality of bonding wires; attaching a light-pervious body to the sensor-type chip, the light-pervious body having a first surface and a second surface opposed to the first surface, wherein a covering layer is disposed on the first surface of the light-pervious body, and a ring-shaped adhesive layer is disposed on the second surface of the light-pervious body and is attached to the active surface of the sensor-type chip; performing a molding process to form an encapsulant on the substrate, wherein the encapsulant encapsulates the sensor-type chip, the bonding wires and the light-pervious body, such that a molded structure is formed; cutting the molded structure according to a predefined size of the sensor-type package; and removing a portion of the encapsulant located on the covering layer so as to expose the light-pervious body. Thus, the sensor-type package is obtained. An adhesive force between the covering layer and the encapsulant is greater than that between the covering layer and the light-pervious body. As a result, the covering layer can be removed simultaneously when the portion of the encapsulant located on the covering layer is removed.

The present invention also discloses a sensor-type package comprising: a substrate; a sensor-type chip attached to the substrate, and having an active surface and a non-active surface opposed to the active surface, wherein the non-active surface of the sensor-type chip is attached to the substrate; a plurality of bonding wires for electrically connecting the active surface of the sensor-type chip to the substrate; a light-pervious body attached to the sensor-type chip, and having a first surface and a second surface opposed to the first surface, wherein a ring-shaped adhesive layer is disposed on the second surface of the light-pervious body and is attached to the sensor-type chip; and an encapsulant formed between the substrate and the light-pervious body, for encapsulating the bonding wires and the sensor-type chip.

A sensor area is formed on the active surface of the sensor-type chip, and can capture light passing through the light-pervious body. The ring-shaped adhesive layer disposed on the second surface of the light-pervious body has a thickness larger than a loop height of the bonding wires, thereby preventing the light-pervious body from contacting and touching the bonding wires. The ring-shaped adhesive layer attached to the active surface of the sensor-type chip can enclose the sensor area of the sensor-type chip, can be located between the sensor area and end portions of the bonding wires connected to the sensor-type chip, or can directly encapsulate the end portions of the bonding wires.

The light-pervious body may have a planar size larger than a predefined planar size of the sensor-type package, such that side surfaces of the light-pervious body can be exposed by the cutting process, so as to facilitate the removal of the covering layer on the first surface of the light-pervious body and the portion of the encapsulant located on the covering layer. This ensures that light can pass through the light-pervious body to be captured by the sensor-type chip. Further, in order to prevent the light-pervious body (for example, made of glass) from cracking in the cutting process, the light-pervious body can firstly be cut by a bevel cutting technique along a predetermined cutting path corresponding to the planar size of the light-pervious body so as to form bevel edges on side surfaces of the light-pervious body, and then the molded structure is cut according to the predefined planar size of the sensor-type package.

The planar size of the light-pervious body can alternatively be slightly smaller than the predefined planar size of the sensor-type package, but has to be larger than a planar size of the sensor-type chip, such that the sensor-type chip can be protected by the light-pervious body. During the cutting process, the bevel cutting technique can be implemented to form bevel edges on a top surface of the encapsulant firstly, and then the molded structure can be cut according to the predefined package size of the sensor-type package. Afterwards, the covering layer on the first surface of the light-pervious body and the portion of the encapsulant located on the covering layer can be removed. Further, a protruding portion can be formed on the top surface of the encapsulant, such that a clamping device can be used to clamp the protruding portion so as to easily remove the covering layer and the portion of the encapsulant located on the covering layer.

To increase the adhesive force between the light-pervious body and the encapsulant and increase the adhesive force between the light-pervious body and the adhesive layer, a rough portion can be formed on the second surface of the light-pervious body at positions corresponding to the encapsulant and the adhesive layer.

The sensor-type package can be fabricated in a batch-type manner using a substrate module plate comprising a plurality of substrates, so as to reduce the fabrication complexity and the fabrication cost.

Therefore, according to the sensor-type package and the fabrication method thereof in the present invention, a sensor-type chip is mounted on a substrate and is electrically connected to the substrate via a plurality of bonding wires; then a light-pervious body is attached to the sensor-type chip, with one surface of the light-pervious body being covered with a covering layer, and another surface of the light-pervious body being formed with an adhesive layer; and subsequently, a molding process is performed to directly form an encapsulant for encapsulating the light-pervious body. As an adhesive force between the covering layer and the encapsulant is greater than that between the covering layer and the light-pervious body, the covering layer and a portion of the encapsulant located on the covering layer can be concurrently removed such that the light-pervious body is exposed and light can pass through the light-pervious body to be captured by the sensor-type chip. Thus, the need of forming a dam structure as in the prior art is eliminated in the present invention, thereby providing a compact sensor-type package, improving the fabrication reliability and reducing the fabrication cost. Moreover, the present invention does not encounter the problems such as leakage of a light-pervious layer and delamination of a dam structure formed by a fluid adhesive in the prior art, thereby further improving the fabrication reliability. Furthermore, the present invention does not have damage to or cracking of bonding wires during attaching the light-pervious layer to the dam structure made of the fluid adhesive in the prior art. Since the conventional molding process is employed in the present invention to directly form the encapsulant for encapsulating the sensor-type chip and supporting the light-pervious body, the fabrication cost is reduced. Also, the conventional molding process helps fabricate the sensor-type package in a batch-type manner using a substrate module plate comprising a plurality of substrates, thereby reducing the fabrication cost and the fabrication complexity.

### BRIEF DESCRIPTION OF DRAWINGS

The present invention can be more fully understood by reading the following detailed description of the preferred embodiments, with reference made to the accompanying drawings, wherein:

FIG. 1 (PRIOR ART) is a schematic cross-sectional diagram of a sensor-type package disclosed by U.S. Pat. No. 6,060,340;

FIGS. 2A and 2B (PRIOR ART) are schematic cross-sectional diagrams of a sensor-type package disclosed by U.S. Pat. Nos. 6,262,479 and 6,590,269;

FIG. 3 (PRIOR ART) is a schematic cross-sectional diagram of a sensor-type package disclosed by U.S. Pat. No. 5,950,074;

FIG. 4A (PRIOR ART) is a schematic cross-sectional diagram of a sensor-type package disclosed by Taiwan Patent No. 521440;

FIG. 4B (PRIOR ART) is a schematic cross-sectional diagram of a sensor-type package disclosed by U.S. Pat. No. 6,995,462;

FIGS. 5A to 5F are schematic diagrams showing a sensor-type package and a fabrication method thereof according to a first embodiment of the present invention;

FIGS. 6A to 6C are schematic diagrams showing a sensor-type package and a fabrication method thereof according to a second embodiment of the present invention;

FIGS. 7A to 7D are schematic diagrams showing a sensor-type package and a fabrication method thereof according to a third embodiment of the present invention;

FIG. 8A to 8D are schematic diagrams showing a sensor-type package and a fabrication method thereof according to a fourth embodiment of the present invention;

FIG. 9 is a schematic diagram of a sensor-type package according to a fifth embodiment of the present invention;

FIGS. 10A and 10B are schematic diagrams showing a fabrication method of a sensor-type package according to a sixth embodiment of the present invention; and

FIG. 11 is a schematic diagram of a sensor-type package according to a seventh embodiment of the present invention.

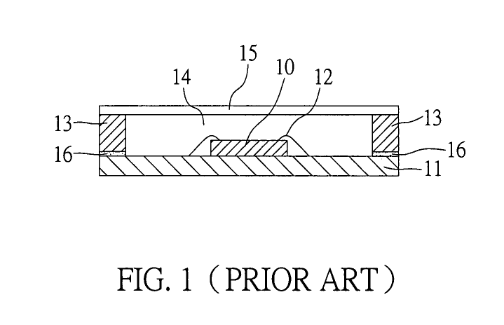

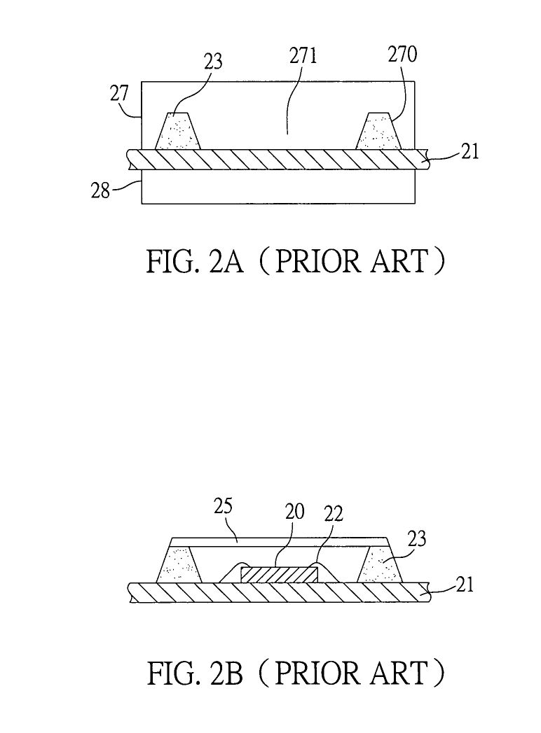

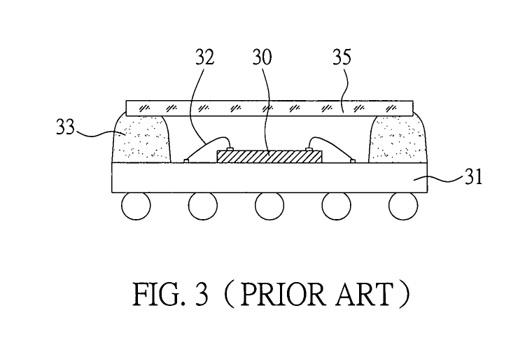

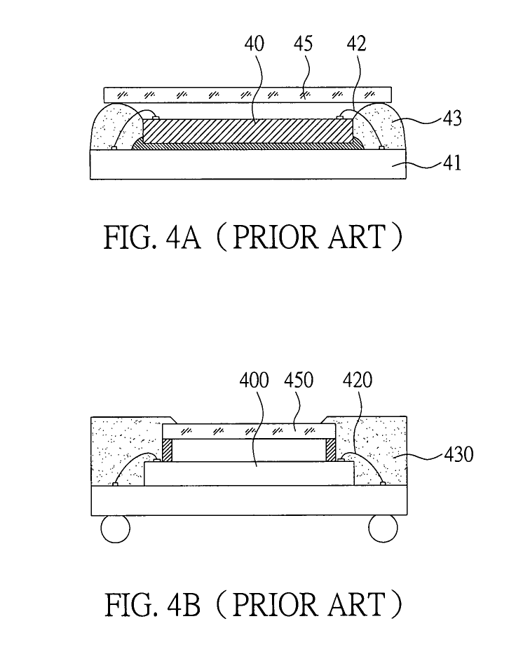

### DETAILED DESCRIPTION OF PREFERRED EMBODIMENTS

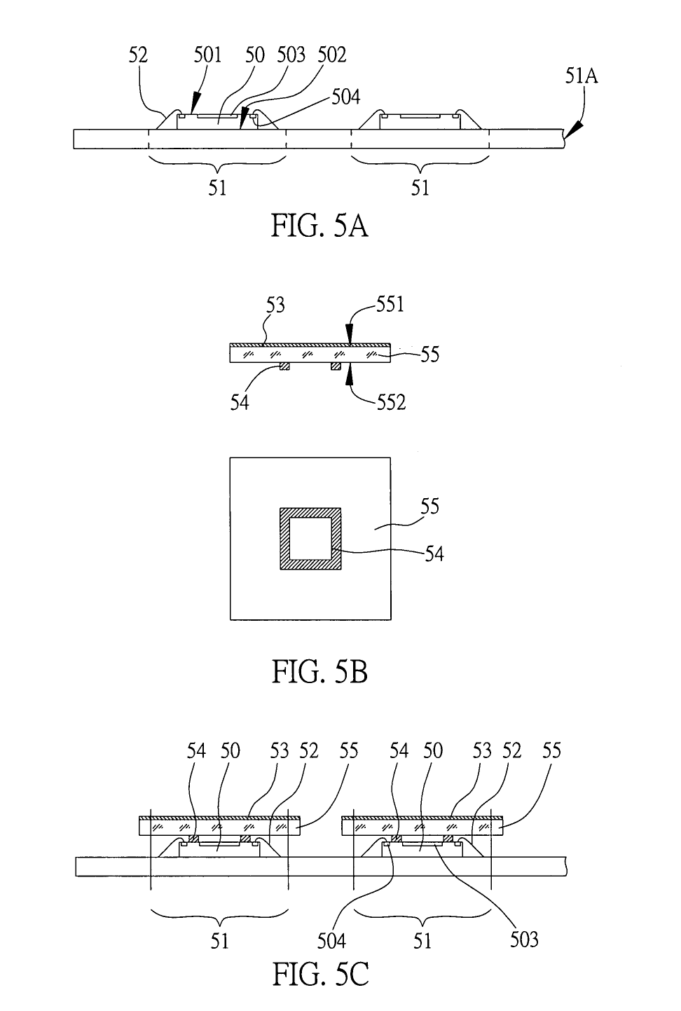

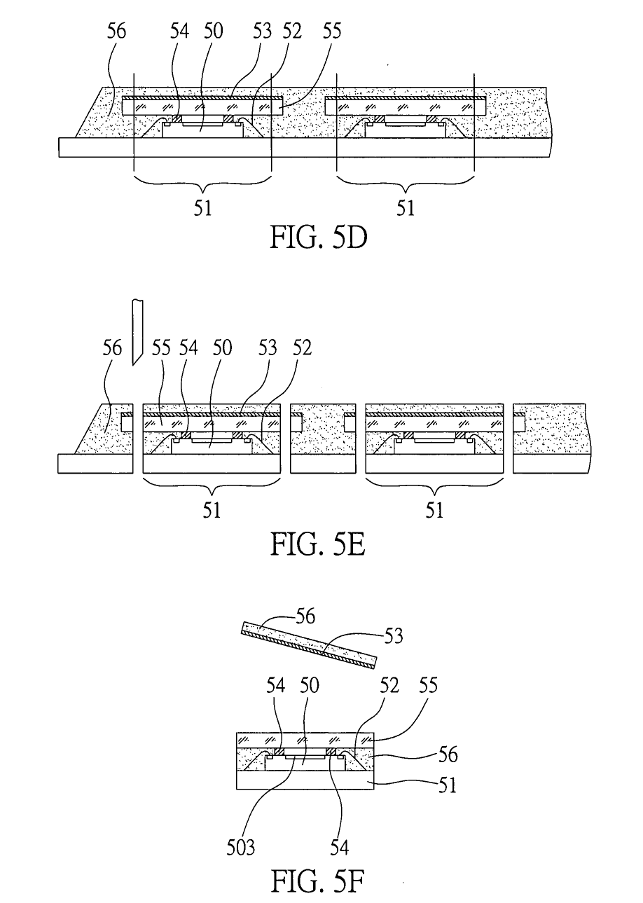

Preferred embodiments of a sensor-type package and a fabrication method thereof proposed in the present invention are described as follows with reference to FIGS. 5 to 11. It should be understood that the drawings are simplified schematic diagrams only showing the elements relevant to the present invention, and the layout of elements could be more complicated in practical implementation.

### First Embodiment

FIGS. 5A to 5F are schematic diagrams showing a sensor-type package and a fabrication method thereof according to a first embodiment of the present invention. In this embodiment, the sensor-type package is fabricated in a batch-type manner.

As shown in FIG. 5A, a substrate module plate 51 A comprising a plurality of substrates 51 is provided, and a sensor-type chip 50 is mounted on each of the substrates 51. A planar size of the sensor-type chip 50 is smaller than a planar size of the substrate 51 that corresponds to a predefined package size. The substrate module plate 51. A may have the plurality of substrates 51 arranged in a matrix or in a strip. The sensor-type chip 50 has an active surface 501 and a non-active surface 502 opposed to the active surface 501, wherein the active surface 501 is formed with a sensor area 503 and a plurality of bonding pads 504 thereon. The non-active surface 502 of the sensor-type chip 50 is attached to the corresponding substrate 51, and the bonding pads 504 of the sensor-type chip 50 are connected to the corresponding substrate 51 by a plurality of bonding wires 52 for electrically connecting the sensor-type chip 50 and the substrate 51. The non-active surface 502 of the sensor-type chip 50 can be thinned firstly and a good die is selected for being attached to the substrate 51.

As shown in FIG. 5B, a light-pervious body 55 is provided, which has a first surface 551 and a second surface 552 opposed to the first surface 551, wherein a covering layer 53 is disposed on the first surface 551 and a ring-shaped adhesive layer 54 is disposed on the second surface 552. The light-pervious body 55 may be made of such as glass. The covering layer 53 may be made of such as a tape, an epoxy resin or a wax material so as to make an adhesive force between the covering layer 53 and the light-pervious body 55 smaller than that between the covering layer 53 and an encapsulant to be subsequently formed over the covering layer 53.

As shown in FIG. 5C, the light-pervious body 55 is attached via the adhesive layer 54 to the sensor-type chip 50 mounted on each of the substrates 51, wherein the adhesive layer 54 has a thickness larger than a loop height of the bonding wires 52 so as to prevent the light-pervious body 55 from contacting the bonding wires 52. Moreover, the ring-shaped adhesive layer 54 is disposed between the sensor area 503 and the bonding pads 504 of the sensor-type chip 50, and encloses the sensor area 503.

As shown in FIG. 5D, a molding process is performed to form an encapsulant 56 on the substrates 51, wherein the encapsulant 56 encapsulates the sensor-type chips 50, the bonding wires 52, the light-pervious bodies 55 and the covering layers 53 on the light-pervious bodies 55, such that a molded structure is obtained.

As shown in FIG. 5E, the molded structure is cut according to the predefined package size (corresponding to the planar size of the substrate 51). Since the planar size of the light-pervious body 55 is larger than the predefined package size, side surfaces of the light-pervious body 55 and the covering layer 53 are exposed through the cutting process, which can facilitate subsequent removal of the covering layer 53 on the light-pervious body 55 and a portion of the encapsulant 56 located on the covering layer 53. After the cutting process, the planar size of the light-pervious body 55 becomes equal to that of the substrate 51 that defines the package size.

As shown in FIG. 5F, as the adhesive force between the covering layer 53 and the encapsulant 56 is greater than that between the covering layer 53 and the light-pervious body 55, the covering layer 53 and the portion of the encapsulant 56 located on the covering layer 53 can be concurrently removed. Thus, the light-pervious body 55 is exposed, and external light can pass through the light-pervious body 55 to reach the sensor area 503 of the sensor-type chip 50 for activating the sensor-type chip 50.

By the above fabrication method, the present invention also discloses a sensor-type package, which comprises: a substrate 51; a sensor-type chip 50 mounted on the substrate 51, the sensor-type chip 50 having an active surface 501 and a non-active surface 502 opposed to the active surface 501, wherein the non-active surface 502 of the sensor-type chip 50 is attached to the substrate 51; a plurality of bonding wires 52 for electrically connecting the active surface 501 of the sensor-type chip 50 to the substrate 51; a light-pervious body 55 attached to the sensor-type chip 50, the light-pervious body 55 having a first surface 551 and a second surface 552 opposed to the first surface 551, wherein a ring-shaped adhesive layer 54 is disposed on the second surface 552 of the light-pervious body 55 and is attached to the sensor-type chip 50; and an encapsulant 56 formed between the substrate 51 and the light-pervious body 55, for encapsulating the bonding wires 52 and the sensor-type chip 50.

Therefore, according to the sensor-type package and the fabrication method thereof in the present invention, a sensor-type chip is mounted on a substrate and is electrically connected to the substrate via a plurality of bonding wires; then a light-pervious body is attached to the sensor-type chip, with one surface of the light-pervious body being covered with a covering layer, and another surface of the light-pervious body being formed with an adhesive layer; and subsequently, a molding process is performed to directly form an encapsulant for encapsulating the light-pervious body. As an adhesive force between the covering layer and the encapsulant is greater than that between the covering layer and the light-pervious body, the covering layer and a portion of the encapsulant located on the covering layer can be concurrently removed such that the light-pervious body is exposed and light can pass through the light-pervious body to be captured by the sensor-type chip. Thus, the need of forming a dam structure as in the prior art is eliminated in the present invention, thereby providing a compact sensor-type package, improving the fabrication reliability and reducing the fabrication cost. Moreover, the present invention does not encounter the problems such as leakage of a light-pervious layer and delamination of a dam structure formed by a fluid adhesive in the prior art, thereby further improving the fabrication reliability. Furthermore, the present invention does not have damage to or cracking of bonding wires during attaching the light-pervious layer to the dam structure made of the fluid adhesive in the prior art. Since the conventional molding process is employed in the present invention to directly form the encapsulant for encapsulating the sensor-type chip and supporting the light-pervious body, the fabrication cost is reduced. Also, the conventional molding process helps fabricate the sensor-type package in a batch-type manner using a substrate module plate comprising a plurality of substrates, thereby reducing the fabrication cost and the fabrication complexity.

### Second Embodiment

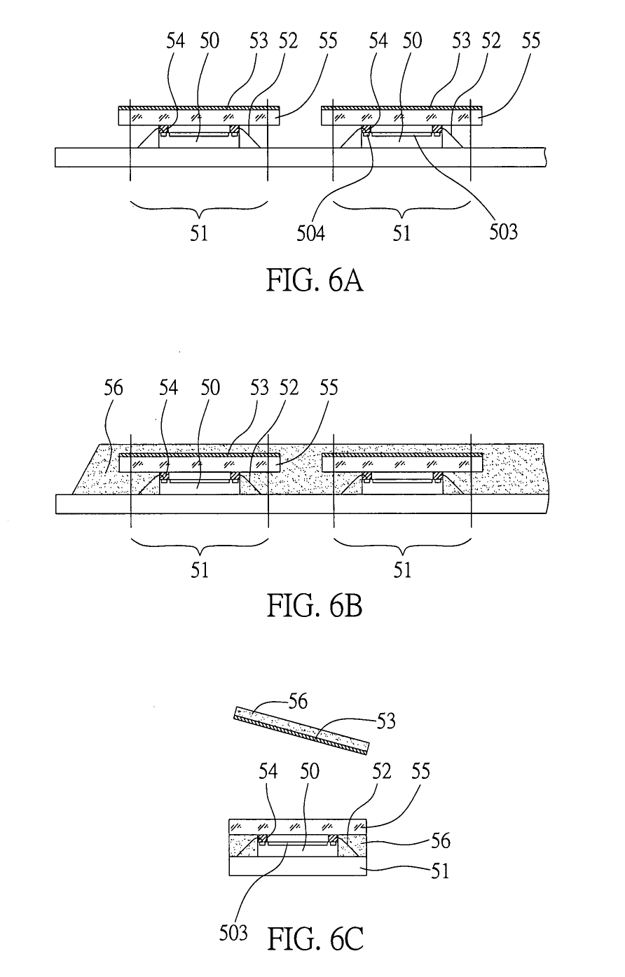

FIGS. 6A to 6C are schematic diagrams showing a sensor-type package and a fabrication method thereof according to a second embodiment of the present invention. The second embodiment is similar to the above first embodiment, and differs from the first embodiment primarily in that, when the sensor area is very close to the bonding pads of the sensor-type chip, for example, with a distance therebetween being smaller than 300 μm, the adhesive layer on the second surface of the light-pervious body cannot be disposed between the sensor area and the bonding pads; instead, the adhesive layer is attached to the bonding pads of the sensor-type chip and encapsulates end portions of the bonding wires connected to the sensor-type chip.

As shown in FIG. 6A, a sensor-type chip 50 is mounted on each of the substrates 51, wherein the sensor-type chip 50 is formed with a sensor area 503 and bonding pads 504 on an active surface thereof. The sensor-type chip 50 is attached via its non-active surface to the corresponding substrate 51, and the bonding pads 504 of the sensor-type chip 50 are electrically connected to the substrate 51 by a plurality of bonding wires 52. A light-pervious body 55 is attached to the sensor-type chip 50 mounted on each of the substrates 51. The light-pervious body 55 has one surface covered with a covering layer 53 and has another surface formed with an adhesive layer 54 formed thereon.

When attaching the light-pervious body 55 to the sensor-type chip 50, the light-pervious body 55 is heated by a heating source provided below the substrate 51 so as to melt the adhesive layer 54. After the melted adhesive layer 54 contacts the bonding wires 52 and encapsulates the end portions of the bonding wires 52, the heating source is removed, and the adhesive layer 54 is solidified to support the light-pervious body 55.

The adhesive layer 54 may be made of a B-stage epoxy resin, which is in a half-melting state and has adhesiveness after the light-pervious body 55 is heated, such that the adhesive layer 54 of the light-pervious body 55 can be attached to the bonding pads 504 of the sensor-type chips 50 and encapsulate the end portions of the bonding wires 52 connected to the bonding pads 504.

As shown in FIG. 6B, a molding process is performed to form an encapsulant 56 on the substrates 51, wherein the encapsulant 56 encapsulates the sensor-type chips 50, the bonding wires 52, the light-pervious bodies 55 and the covering layers 53 on the light-pervious bodies 55, such that a molded structure is obtained.

As shown in FIG. 6C, the molded structure is cut according to the predefined package size (corresponding to the planar size of the substrate 51). The covering layer 53 on the light-pervious body 55 and a portion of the encapsulant 56 located on the covering layer 53 are removed so as to expose the light-pervious body 55.

### Third Embodiment

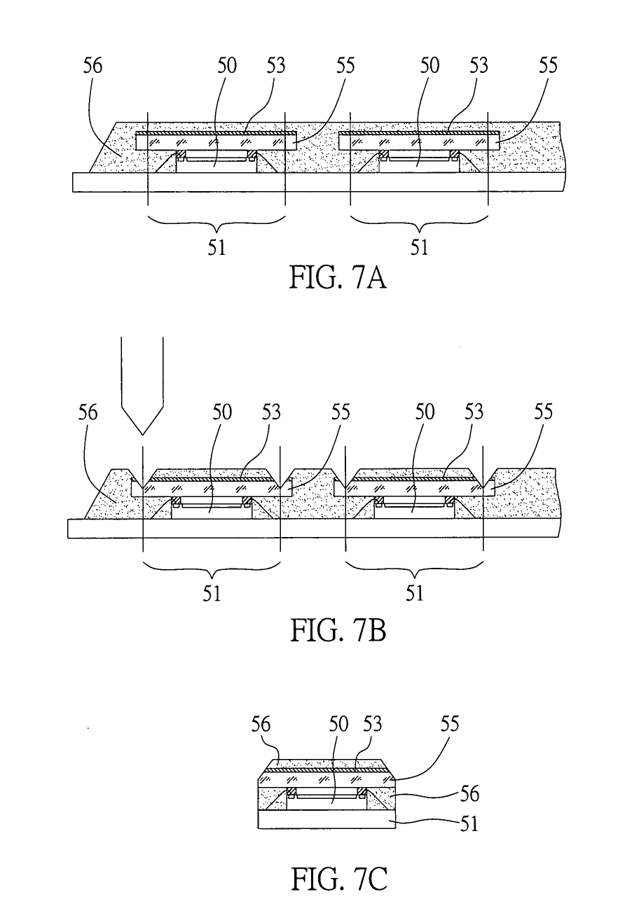

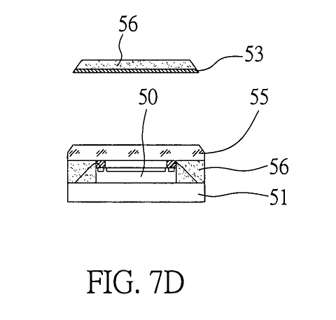

FIGS. 7A to 7D are schematic diagrams showing a sensor-type package and a fabrication method thereof according to a third embodiment of the present invention. The third embodiment is similar to the above embodiments, and differs from the above embodiments primarily in that, when the light-pervious body has a size larger than the predefined package size, a cutting path would pass through the light-pervious body, and a bevel cutting technique is employed to form bevel edges on side surfaces of the light-pervious body so as to prevent the light-pervious body (made of such as glass) from cracking during the cutting process.

As shown in FIGS. 7A and 7B, after mounting the sensor-type chips 50 on the substrates 51, forming the bonding wires 52, and attaching the light-pervious bodies 55 to the sensor-type chips 50, and performing the molding process to form the encapsulant 56 on the substrates 51, a bevel cutting technique is implemented to cut the encapsulant 56, the light-pervious bodies 55 and the covering layers 53 along a predetermined cutting path corresponding to the predefined package size, so as to form bevel edges on side surfaces of the light-pervious bodies 55.

As shown in FIGS. 7C and 7D, a second cutting step is performed along the bevel edges of the light-pervious bodies 55 according to the predefined package size so as to separate the substrates 51 from each other, such that the light-pervious bodies can be prevented from cracking during the cutting process. Subsequently, the covering layer 53 and the portion of the encapsulant 56 located on the covering layer 53 can be removed.

### Fourth Embodiment

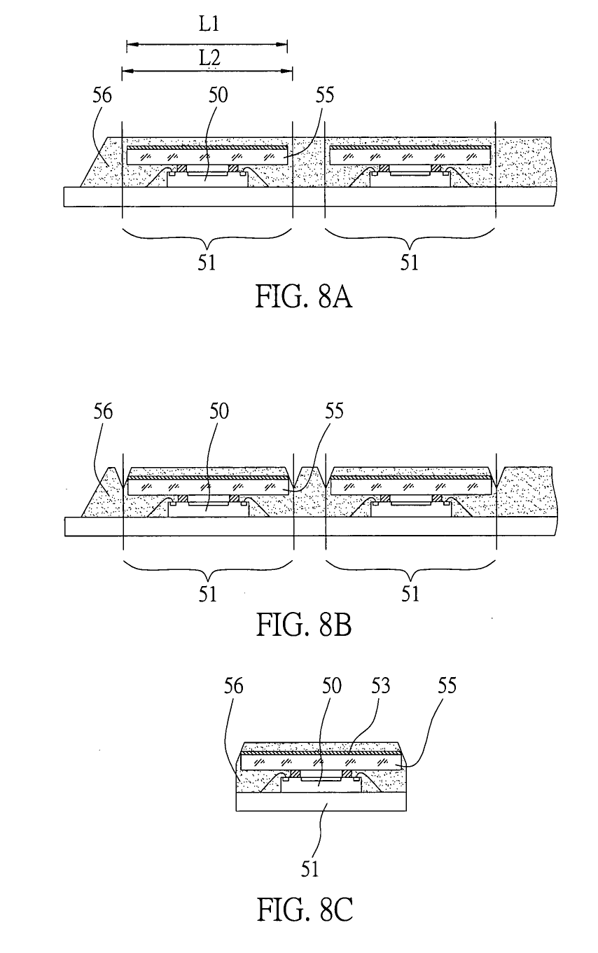

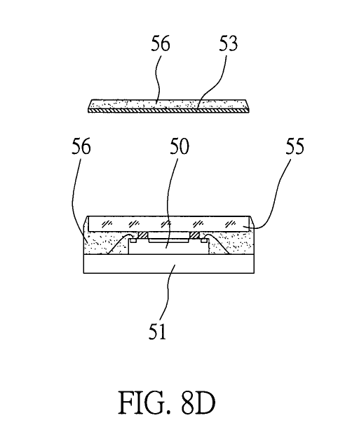

FIGS. 8A to 8D are schematic diagrams showing a sensor-type package and a fabrication method thereof according to a fourth embodiment of the present invention. The fourth embodiment is similar to the above embodiments, and differs from the above embodiments primarily in that, the size of the light-pervious body is slightly smaller than the predefined package size, but is still larger than the size of the sensor-type chip to protect the sensor-type chip.

As shown in FIGS. 8A and 8B, after mounting the sensor-type chips 50 on the substrates 51, forming the bonding wires 52, and attaching the light-pervious bodies 55 to the sensor-type chips 50, and performing the molding process to form the encapsulant 56 on the substrates 51, a bevel cutting technique is implemented to cut the encapsulant 56 along a predetermined cutting path corresponding to the predefined package size, so as to form bevel edges on a top surface of the encapsulant 56. The planar size L1 of the light-pervious body 55 is smaller than the predefined planar size L2 of the package (corresponding to the size of the substrate 51) by about 0.1 to 2.0 mm, and preferably by 1 mm, so as to allow side surfaces of the covering layer 53 to be exposed by the cutting process. In addition, the size of the light-pervious body 55 is larger than the size of the sensor-type chip 50 and extends beyond a wire-bonding area where the bonding wires are formed, so as to protect the sensor-type chip and the bonding wires.

As shown in FIGS. 8C and 8D, a second cutting step is performed along the bevel edges of the encapsulant 56 according to the predefined package size so as to separate the substrates 51 from each other. Subsequently, the covering layer 53 and the portion of the encapsulant 56 located on the covering layer 53 can be removed.

### Fifth Embodiment

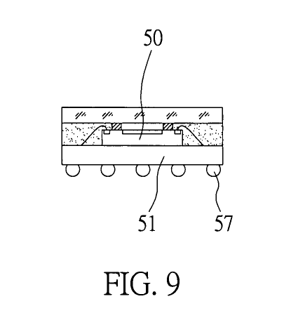

FIG. 9 is a schematic diagram of a sensor-type package according to a fifth embodiment of the present invention. The fifth embodiment is similar to the above embodiments, and differs from the above embodiments primarily in that, a plurality of solder balls 52 are implanted on a surface of the substrate 51 other than the surface for mounting the sensor-type chip 50, and are used to electrically connect the sensor-type package to an external device.

### Sixth Embodiment

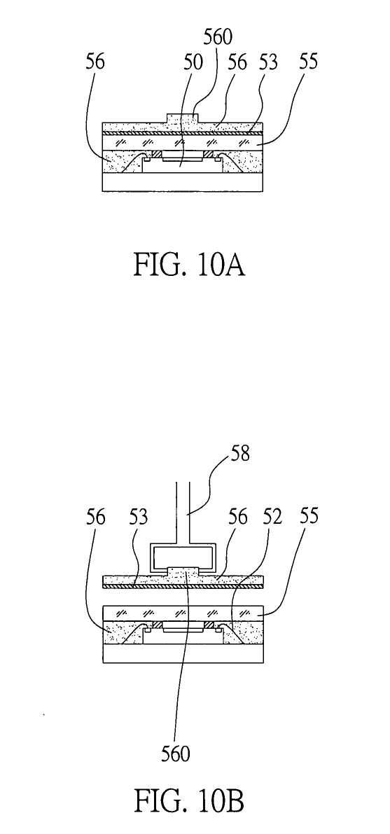

FIGS. 10A and 10B are schematic diagrams showing a fabrication method of a sensor-type package according to a sixth embodiment of the present invention. The sixth embodiment is similar to the above embodiments, and differs from the above embodiments primarily in that, for facilitating the removal of the covering layer 53 and the portion of the encapsulant 56 located on the covering layer 53, a protruding portion 560 is formed on the top surface of the encapsulant 56, such that a clamping device 58 can be used to clamp the protruding portion 560 so as to remove the covering layer 53 and the portion of the encapsulant 56 located on the covering layer 53.

### Seventh Embodiment

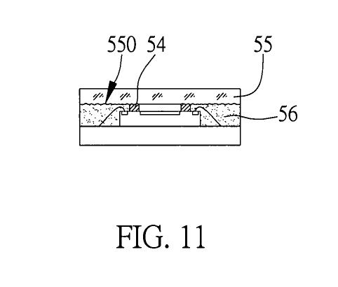

FIG. 11 is a schematic diagram of a sensor-type package according to a seventh embodiment of the present invention. The seventh embodiment is similar to the above embodiments, and differs from the above embodiments primarily in that, to increase the adhesive force between the light-pervious body 55 and the encapsulant 56 as well as the adhesive force between the light-pervious body 55 and the adhesive layer 54, a rough portion 550 is formed on the second surface of the light-pervious body 55 at positions corresponding to the encapsulant 56 and the adhesive layer 54. It should be noted that the rough portion 550 is not formed at a position corresponding to the sensor area of the sensor-type chip.

The present invention is illustrated with exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A fabrication method of a sensor-type package, comprising the steps of:
attaching a sensor-type chip to a substrate, the sensor-type chip having an active surface and a non-active surface opposed to the active surface, wherein the non-active surface of the sensor-type chip is attached to the substrate, and the active surface of the sensor-type chip is electrically connected to the substrate via a plurality of bonding wires;
attaching a light-pervious body to the sensor-type chip, the light-pervious body having a first surface and a second surface opposed to the first surface, wherein a covering layer is disposed on the first surface of the light-pervious body, and a ring-shaped adhesive layer is disposed on the second surface of the light-pervious body and is attached to the active surface of the sensor-type chip;
performing a molding process to form an encapsulant on the substrate, wherein the encapsulant encapsulates the sensor-type chip, the bonding wires and the light-pervious body, such that a molded structure is formed;
cutting the molded structure according to a predefined size of the sensor-type package; and
removing a portion of the encapsulant located on the covering layer so as to expose the light-pervious body, such that the sensor-type package is obtained.

2. The fabrication method of claim 1, wherein the non-active surface of the sensor-type chip is thinned before being attached to the substrate.

3. The fabrication method of claim 1, wherein an adhesive force between the covering layer and the encapsulant is greater than that between the covering layer and the light-pervious body, such that the covering layer is removed simultaneously when the portion of the encapsulant located on the covering layer is removed.

4. The fabrication method of claim 1, wherein the active surface of the sensor-type chip is formed with a sensor area and bonding pads thereon, and the adhesive layer is disposed between the sensor area and the bonding pads of the sensor-type chip and encloses the sensor area.

5. The fabrication method of claim 1, wherein the adhesive layer is attached to bonding pads of the sensor-type chip, and encapsulates end portions of the bonding wires connected to the sensor-type chip.

6. The fabrication method of claim 5, wherein during attaching the light-pervious body to the sensor-type chip, the light-pervious body is heated by a heating source provided below the substrate to melt the adhesive layer, and when the melted adhesive layer contacts the bonding wires and encapsulates the end portions of the bonding wires, the heating source is removed, such that the adhesive layer is solidified and supports the light-pervious body.

7. The fabrication method of claim 6, wherein the adhesive layer is made of a B-stage epoxy resin, which is in a half-melting state and has adhesiveness when the light-pervious body is heated, such that the adhesive layer of the light-pervious body is attached to the bonding pads of the sensor-type chip and encapsulates the end portions of the bonding wires connected to the bonding pads.

8. The fabrication method of claim 1, wherein the light-pervious body is made of glass, and the covering layer is made of one of a tape, an epoxy resin and a wax material so as to allow an adhesive force between the covering layer and the light-pervious body to be smaller than that between the covering layer and the encapsulant.

9. The fabrication method of claim 1, wherein the adhesive layer has a thickness larger than a loop height of the bonding wires.

10. The fabrication method of claim 1, wherein the light-pervious body has a planar size larger than a predefined planar size of the sensor-type package.

11. The fabrication method of claim 10, wherein during cutting the molded structure, the encapsulant, the light-pervious body and the covering layer are cut by a bevel cutting process along a predetermined cutting path corresponding to the predefined planar size of the sensor-type package so as to form bevel edges on side surfaces of the light-pervious body, and then the molded structure is cut according to the predefined planar size of the sensor-type package.

12. The fabrication method of claim 1, wherein the light-pervious body has a planar size smaller than a predefined planar size of the sensor-type package and larger than a planar size of the sensor-type chip.

13. The fabrication method of claim 12, wherein during cutting the molded structure, the encapsulant is cut by a bevel cutting process along a predetermined cutting path corresponding to the predefined planar size of the sensor-type package so as to form bevel edges on a top surface of the encapsulant, and then the molded structure is cut according to the predefined planar size of the sensor-type package.

14. The fabrication method of claim 12, wherein the planar size of the light-pervious body is smaller than the predefined planar size of the sensor-type package by 0.1 to 2.0 mm.

15. The fabrication method of claim 1, wherein a protruding portion is formed on a top surface of the encapsulant.

16. The method of claim 1, wherein the second surface of the light-pervious body is formed with a rough portion at positions corresponding to the adhesive layer and the encapsulant.

17. A sensor-type package comprising:
a substrate;
a sensor-type chip attached to the substrate, and having an active surface and a non-active surface opposed to the active surface, wherein the non-active surface of the sensor-type chip is attached to the substrate;
a plurality of bonding wires for electrically connecting the active surface of the sensor-type chip to the substrate;
a light-pervious body attached to the sensor-type chip, and having a first surface and a second surface opposed to the first surface, wherein a ring-shaped adhesive layer is disposed on the second surface of the light-pervious body and is attached to the sensor-type chip; and
an encapsulant formed between the substrate and the light-pervious body, for encapsulating the bonding wires and the sensor-type chip.

18. The sensor-type package of claim 17, wherein the non-active surface of the sensor-type chip is thinned.

19. The sensor-type package of claim 17, wherein the active surface of the sensor-type chip is formed with a sensor area and bonding pads thereon, and the adhesive layer is disposed between the sensor area and the bonding pads of the sensor-type chip and encloses the sensor area.

20. The sensor-type package of claim 17, wherein the adhesive layer is attached to bonding pads of the sensor-type chip, and encapsulates end portions of the bonding wires connected to the sensor-type chip.

21. The sensor-type package of claim 17, wherein the light-pervious body is made of glass.

22. The sensor-type package of claim 17, wherein the adhesive layer has a thickness larger than a loop height of the bonding wires.

23. The sensor-type package of claim 17, wherein the light-pervious body has a planar size equal to a predefined planar size of the sensor-type package.

24. The sensor-type package of claim 17, wherein the light-pervious body has a planar size smaller than a predefined planar size of the sensor-type package and larger than a planar size of the sensor-type chip.

25. The sensor-type package of claim 24, wherein the planar size of the light-pervious body is smaller than the predefined planar size of the sensor-type package by 0.1 to 2.0 mm.

26. The sensor-type package of claim 17, wherein the light-pervious body is formed with bevel edges on side surfaces thereof.

27. The sensor-type package of claim 17, wherein the second surface of the light-pervious body is formed with a rough portion at positions corresponding to the adhesive layer and the encapsulant.
